(19) United States
(12) Patent Application Publication
(10) Pub. No.: US 2014/0167206 A1
(43) Pub. Date: Jun. 19, 2014

(54) SHALLOW TRENCH ISOLATION STRUCTURE AND METHOD OF MANUFACTURE

(71) Applicant: MACRONIX INTERNATIONAL CO., LTD., Hsinchu (TW)

(72) Inventors: MING-TSUNG WU, Zhubei City (TW); SHIH-PING HONG, Taichung City (TW)

(73) Assignee: MACRONIX INTERNATIONAL CO., LTD., Hsinchu (TW)

(21) Appl. No.: 13/716,522

(22) Filed: Dec. 17, 2012

(51) Int. Cl. H01L 29/06; H01L 21/76

(52) U.S. Cl. CPC H01L 29/0642; H01L 21/76
USPC 257/499; 438/400

(57) ABSTRACT

A semiconductor device includes a substrate and a first and second plurality of stack structures arranged over the substrate. The first and second plurality of stack structures are separated by a gap. The substrate includes a first trench between the structures of the first plurality of stack structures, a second trench between the structures of the second plurality of stack structures, and a third trench in the gap. A depth of the first trench is less than a depth of the third trench.

### BACKGROUND

The present application relates generally to semiconductor devices and includes methods and apparatus for improving trench isolation structures.

An important capability for manufacturing reliable integrated circuits is to isolate structures. One way to isolate structures is to provide a trench between them, sometimes referred to as Shallow Trench Isolation (STI). With the reduction of size and increasing density of semiconductor structures, there will often be boundaries between a dense region and a less dense region. For example, between an array region in a memory device and a periphery region. The isolation trench depth in the dense regions (e.g., the array region) and the less dense regions (e.g., the periphery) is often different. This is due to several factors related to structural aspects and performance aspects of the device. The aspect ratio of the array region is increasing as structure size is decreasing. That is, the ratio of the height of the structure to the width of the structure is increasing. If the trench depth in the array region is too deep, then the structural integrity of the structures in the array may be comprised leading to reduced reliability of the device. In addition, higher voltage signals are often used in the periphery regions as compared to array regions leading to a need for deeper isolation trenches in the periphery regions for good isolation characteristics.

Providing different trench depth in different regions of a device is a complicated process requiring many process steps. In addition, at a threshold between a region with a shallower trench and a region with a deeper trench, existing techniques provide a sharp discontinuity leading to undesirable high trench loading. High trench loading can lead to stress fractures and cracks, which negatively affect device performance.

### BRIEF SUMMARY

In an embodiment, a semiconductor device includes a substrate and a first and second plurality of stack structures arranged over the substrate. The first plurality of stack structures is arranged more densely than the second plurality of stack structures. The first and second plurality of stack structures are separated by a gap. The substrate includes a first trench between the structures of the first plurality of stack structures, a second trench between the structures of the second plurality of stack structures, and a third trench in the gap. A depth of the first trench is less than a depth of the third trench.

In another embodiment, a method of manufacturing a semiconductor device includes: providing a substrate; forming a plurality of stack structures on the substrate, a portion of the stack structures being defined as an array region and a portion of the stack structures being defined as a periphery region; and forming a plurality of trenches including a plurality of first trenches in the array region, a plurality of second trenches in the periphery region, and at least one third trench in the interface between the array region and the periphery region. The second trenches and the third trench are deeper than the first trenches.

### BRIEF DESCRIPTION OF THE DRAWINGS

FIG. 1 is a side cross-sectional view of an exemplary semiconductor device.

FIG. 2 is a side cross-sectional view of an exemplary semiconductor device.

FIG. 3 is a side cross-sectional view of an exemplary semiconductor device.

FIG. 4 is a side cross-sectional view of an exemplary semiconductor device.

FIG. 5 is a side cross-sectional view of an exemplary semiconductor device.

FIG. 6 is a side cross-sectional view of an exemplary semiconductor device.

FIG. 7 is a side cross-sectional view of an exemplary semiconductor device.

FIG. 8 is a top view of an exemplary semiconductor device.

FIG. 9 is a side cross-sectional view of an exemplary semiconductor device.

FIG. 10 is a side cross-sectional view of an exemplary semiconductor device.

FIG. 11 is a side cross-sectional view of an exemplary semiconductor device.

FIG. 12 is a side cross-sectional view of an exemplary semiconductor device.

FIG. 13 is a side cross-sectional view of an exemplary semiconductor device.

FIG. 14 is a side cross-sectional view of an exemplary semiconductor device.

FIG. 15 is a side cross-sectional view of an exemplary semiconductor device.

FIG. 16 is a side cross-sectional view of an exemplary semiconductor device.

FIG. 17 is a side cross-sectional view of an exemplary semiconductor device.

FIG. 18 is a side cross-sectional view of an exemplary semiconductor device.

FIG. 19 is a side cross-sectional view of an exemplary semiconductor device.

FIG. 20 is a side cross-sectional view of an exemplary semiconductor device.

FIG. 21 is a side cross-sectional view of an exemplary semiconductor device.

FIG. 22 is a top view of an exemplary semiconductor device.

FIG. 23 is a side cross-sectional view of an exemplary semiconductor device.

FIG. 24 is a side cross-sectional view of an exemplary semiconductor device.

### DETAILED DESCRIPTION

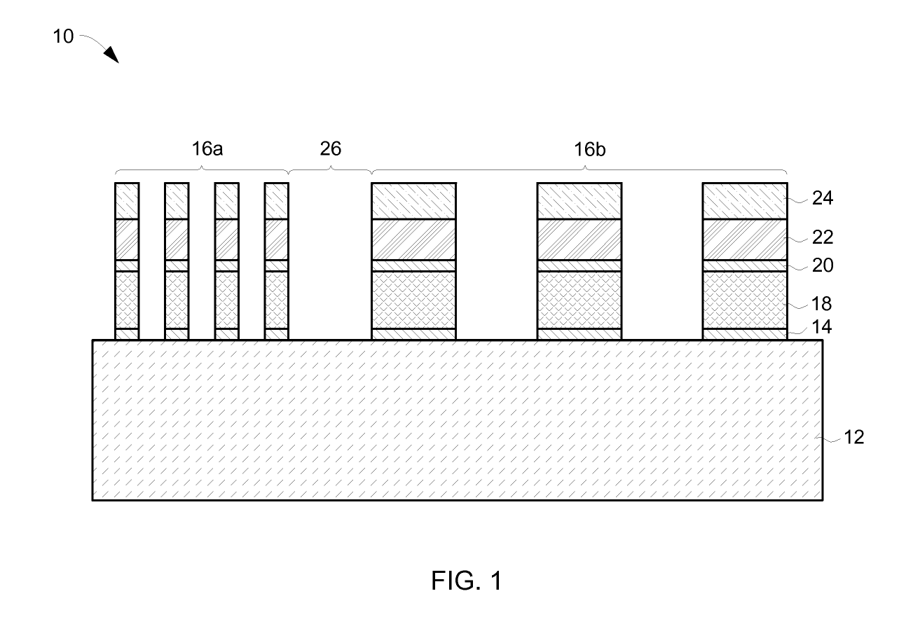

Referring to FIG. 1, a semiconductor device 10 includes a substrate 12 and a dielectric layer 14 over the substrate 12. The substrate 12 may be a silicon substrate. The dielectric layer 14 may be an oxide layer. Structures 16a and 16b are formed over the dielectric layer 14. The structures 16 include a polysilicon layer 18, a buffer dielectric layer 20, a film 22 and a dielectric layer 24. The buffer dielectric layer 20 may be an oxide; the film 20 may be a SiN layer; and the dielectric layer 24 may be an oxide. The structures 16a are formed more densely than the structures 16b. For example, the structures 16a may be an array region of a memory device and the structures 16b may be in a periphery region of the memory device. The structures 16a and 16b are adjacent and separated by a gap 26. In some embodiments, a thickness of the dielectric layer 14 in the region of the structures 16a may be different than a thickness of the dielectric layer 14 in the region of the structures 16b.

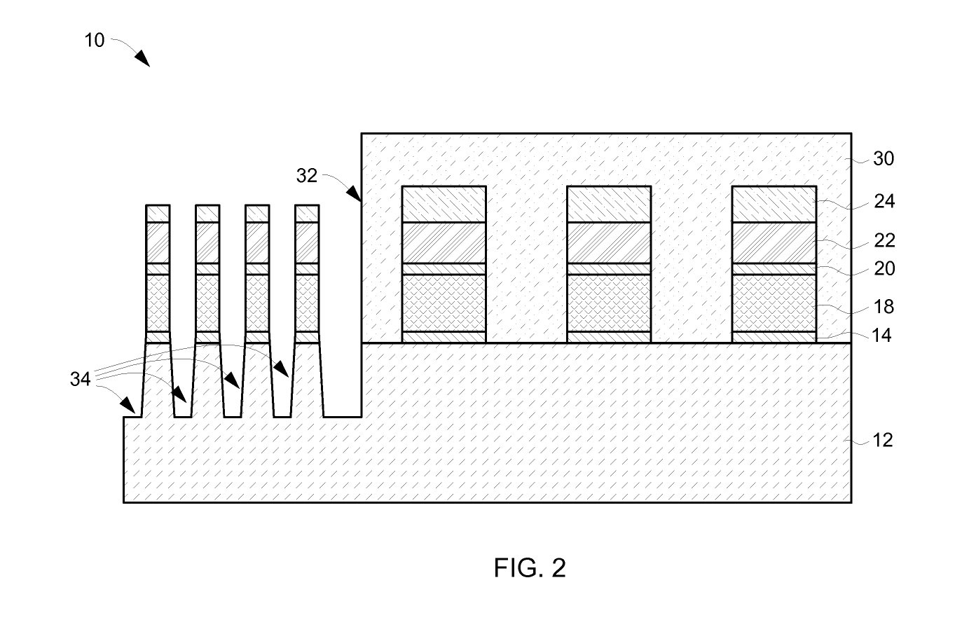

Referring to FIG. 2, a mask 30 is applied to the semiconductor device 10 shown in FIG. 1 and patterned to cover the structures 16b and expose the structures 16a. A boundary 32 between the masked portion and unmasked portion is located in the gap 26. An etching process is performed to form the trenches 34 into the substrate 12. The etching process may be an anisotropic etch and may remove some material from the dielectric layer 24 in the structures 16a.

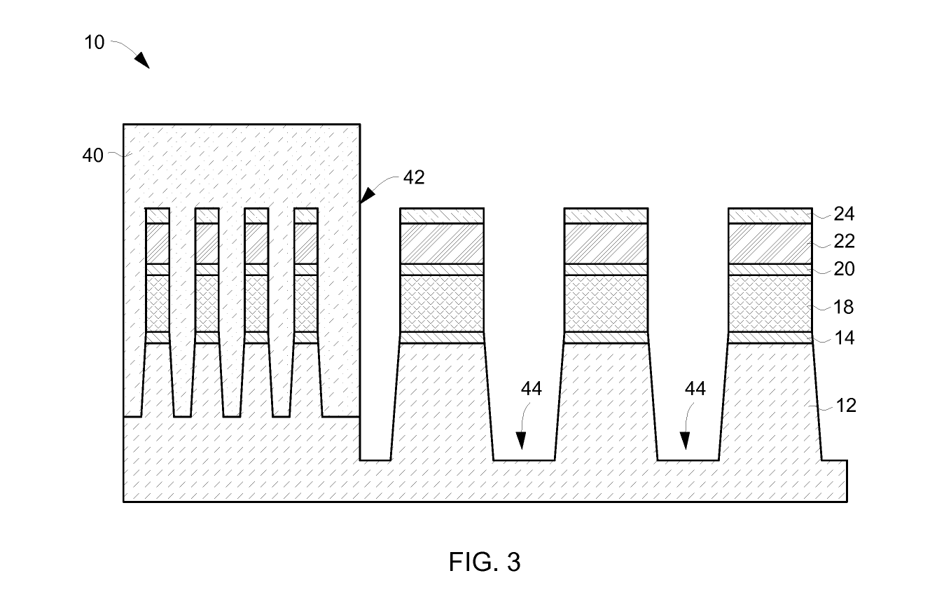

Referring to FIG. 3, the mask 30 is removed and the mask 40 is applied and patterned to cover the structures 16a and expose the structures 16b. A boundary 42 between the masked portion and unmasked portion is located in the gap 26 approximately at the same location as the boundary 32 shown in FIG. 2. An etching process is performed to form the trenches 44 into the substrate 12. The etching process may be an anisotropic etch and may remove some material from the dielectric layer 24 in the structures 16b.

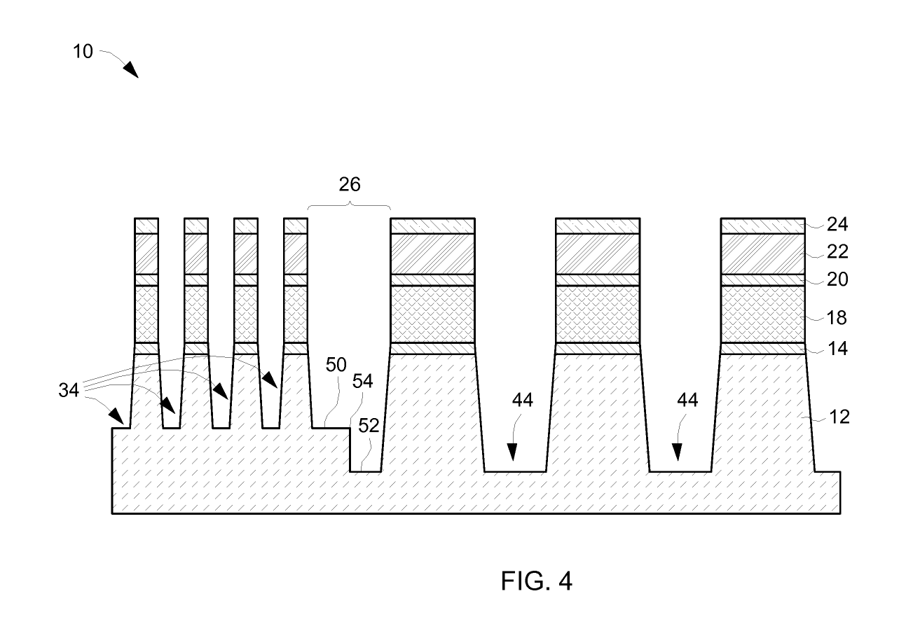

Referring to FIG. 4, the mask 40 is removed. The semiconductor device 10 includes trenches 34 in the region corresponding to the structures 16a and trenches 44 in the region corresponding to the structures 16b. In the gap 26, there is a trench having a portion 50 corresponding to the depth of the trenches 34 and a portion 52 corresponding to the depth of the trenches 44. The abrupt transition 54 between the shallow depth corresponding to the trenches 34 and the deeper depth corresponding to the trenches 44 causes high trench loading, which can lead to stress cracks and fractures and poor device performance. In addition, this method requires at least two photo mask application and patterning steps to provide a different trench depth between the structures 16a and between the structures 16b.

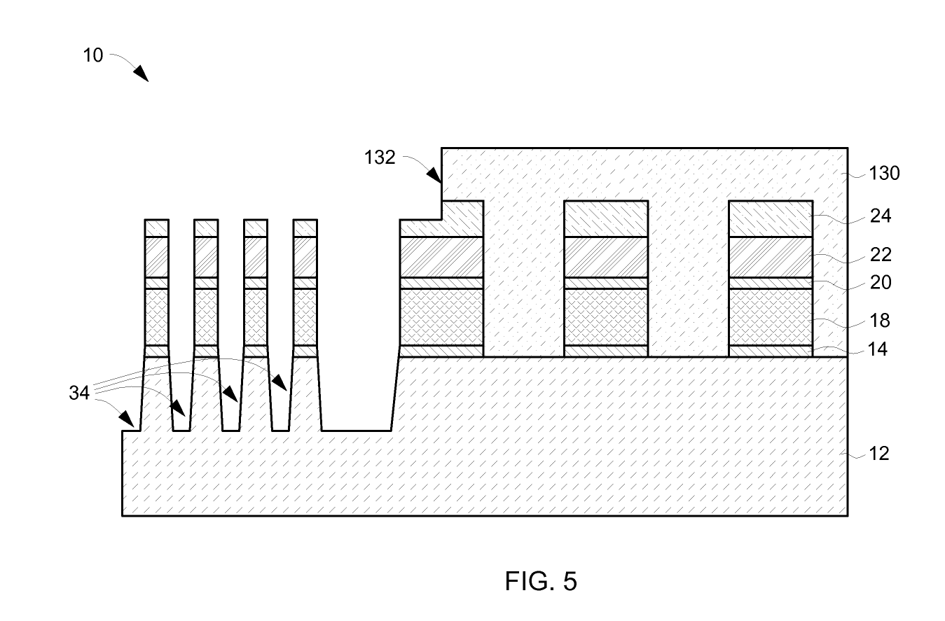

Referring to FIG. 5, a mask 130 is applied to the semiconductor device 10 shown in FIG. 1 and patterned to cover the structures 16b and expose the structures 16a. A boundary 132 between the masked portion and unmasked portion is located on the structure 16b adjacent to the structures 16a across the gap 26. An etching process is performed to form the trenches 34 into the substrate 12. The etching process may be an anisotropic etching and may remove some material from the dielectric layer 24 in the structures 16a. Because the gap 26 is not covered by the mask 130, a trench is formed in the wide gap 26 at a depth corresponding to that of the dense region of the structures 16a.

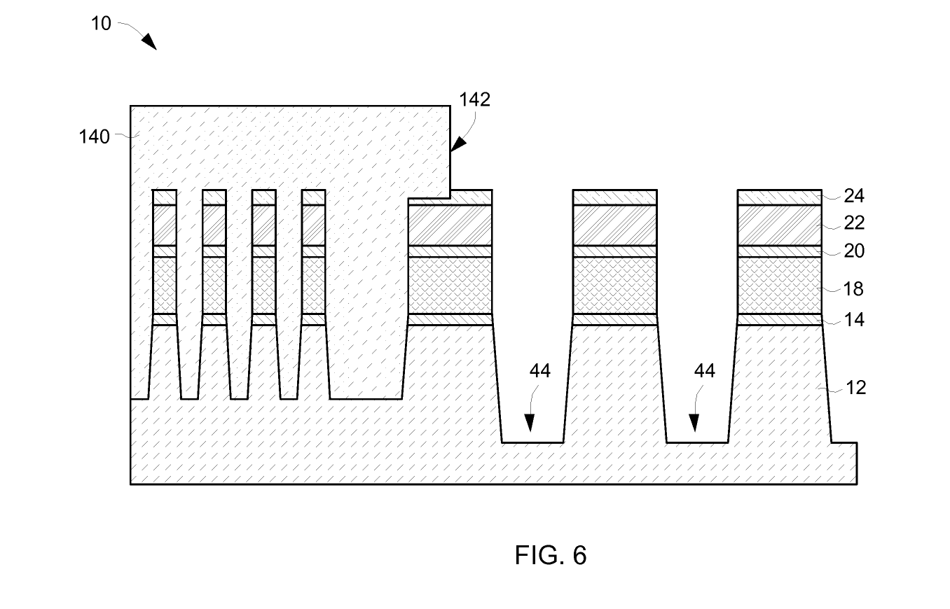

Referring to FIG. 6, the mask 130 is removed and the mask 140 is applied and patterned to cover the structures 16a and expose the structures 16b. A boundary 142 between the masked portion and unmasked portion is located on the structure 16b adjacent to the structures 16a across the gap 26 approximately at the same location as the boundary 132 shown in FIG. 5. The mask 140 covers the gap 26. An etching process is performed to form the trenches 44 into the substrate 12. The etching process may be an anisotropic etch and may remove some material from the dielectric layer 24 in the structures 16b.

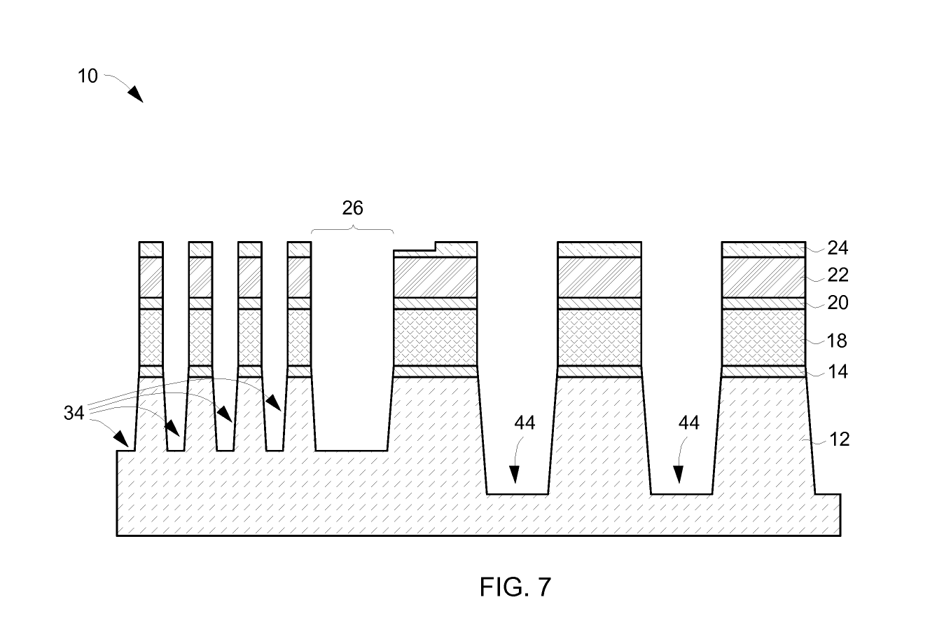

Referring to FIG. 7, the mask 140 is removed. The semiconductor device 10 includes the trenches 34 in the region corresponding to the structures 16a and the trenches 44 in the region corresponding to the structures 16b. In the gap 26, there is a trench having a depth corresponding to the depth of the trenches between the denser structures 16a. The shallow depth of the trench in the wide gap 26 corresponding to the trench depth between the structures 16a rather than the trench depth between the structures 16b is disadvantageous as it provides less insulation for the denser structures 16a from higher voltages that may be present in the less dense structures 16b.

The depth of the trench in the gap 26 may be represented by D_{P1}. The depth of the trenches between the structures 16b may be represented by D_{P2}. The depth of the trenches between the structures 16a may be represented by D_{array}. Different aspect ratios and feature densities may lead to different etching rates (for example a slower etch rate in areas of smaller feature size) in the trench in the gap 26 and the trenches between the structures 16a. Thus, D_{P1} may be different than D_{array}. Then, the trench loading may be represented by (1) D_{P1}−D_{array}; (2) D_{P2}−D_{array}; and (3) (D_{P2}−D_{P1})/D_{P2}* 100%. Equation (3) is preferably large greater than 20%. That is, it is preferable for D_{P1} to be as close to D_{P2} as possible.

In addition, this method requires at least two photo mask application and patterning steps to provide a different trench depth between the structures 16a and between the structures 16b.

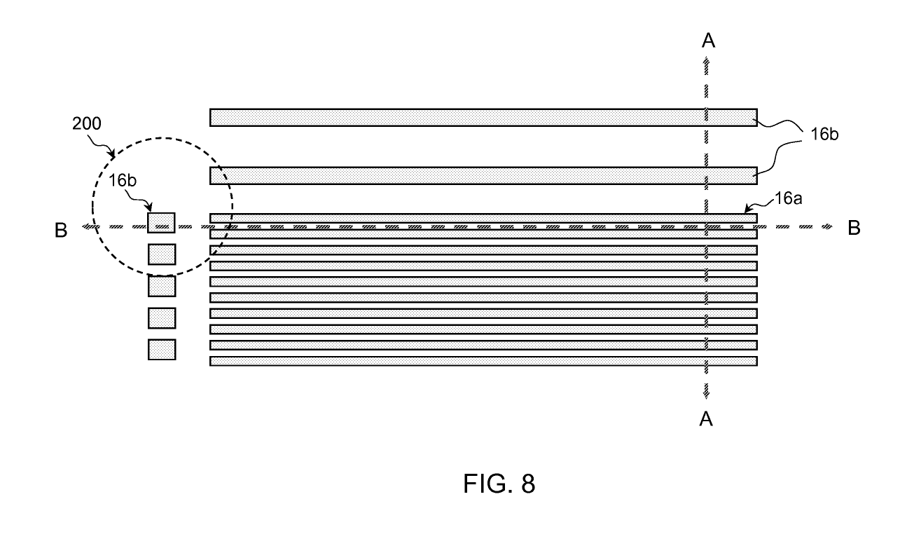

FIG. 8 is a top view of a semiconductor device 10 having a region of dense structures 16a, such as an array region, and a region of less dense structures 16b, such as a periphery region, around the region of dense structures 16a. The cross sectional views of FIGS. 1-7 correspond with a cut line such as the cut line A.

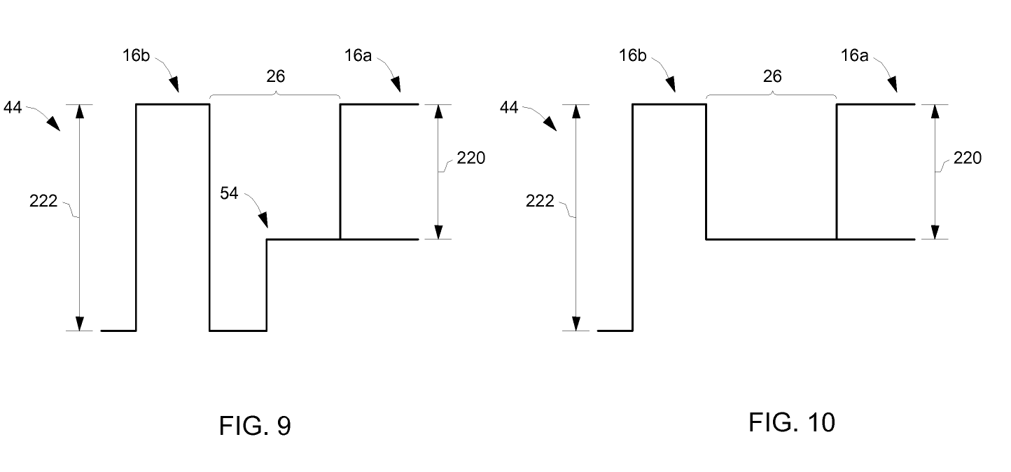

FIG. 9 illustrates a cross-sectional view of the semiconductor device 10 processed as in FIGS. 2-4 in the region 200 along the cut line B. The cut line B is along the trench 34 between the dense structures 16a. Thus, a side profile of a structure 16a is viewed. The depth 220 corresponds with the depth of the trenches 34. The gap 26 between the structure 16a and the structure 16b includes the abrupt transition 54 between the shallow depth corresponding to the trenches 34 and the deeper depth corresponding to the trenches 44. A depth 222 corresponds with a depth of the trenches 44 between the less dense structures 16b.

FIG. 10 illustrates a cross-sectional view of the semiconductor device 10 processed as in FIGS. 5-7 in the region 200 along the cut line B. The cut line B is along the trench 34 between the dense structures 16a. Thus, a side profile of a structure 16a is viewed. The depth 220 corresponds with the depth of the trenches 34. The gap 26 between the structure 16a and the structure 16b has a depth corresponding with the denser structures 16a. A depth 222 corresponds with a depth of the trenches 44 between the less dense structures 16b.

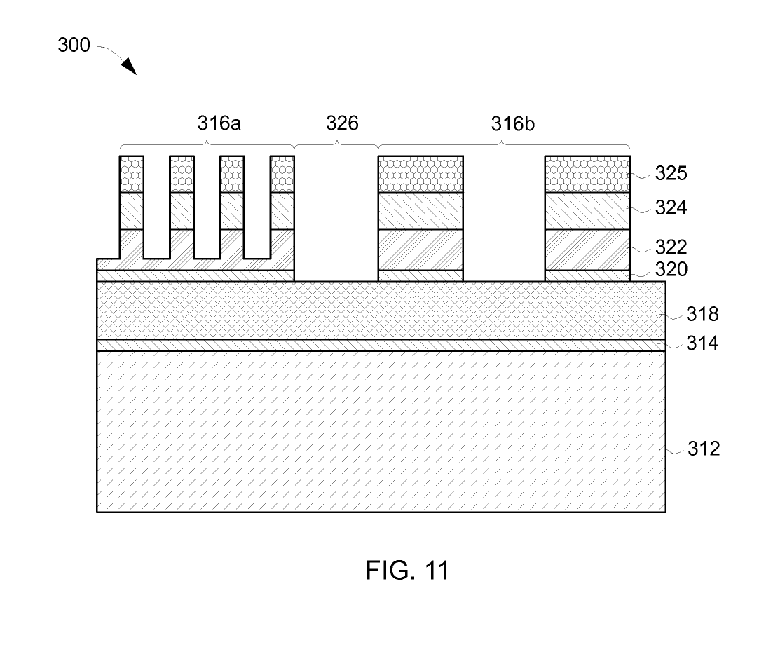

Referring to FIG. 11, a semiconductor device 300 includes a substrate 312, a dielectric layer 314 over the substrate 312, and a polysilicon layer 318 over the dielectric layer 314. The substrate 312 may be a silicon substrate. The dielectric layer 314 may be an oxide layer. Structures 316a and 316b are formed over the dielectric layer 314. The structures 316 include a buffer dielectric layer 320, a film 322, a dielectric layer 324, and a patterning film 325. The buffer dielectric layer 320 may be an oxide; the film 322 may be a SiN layer; and the dielectric layer 324 may be an oxide. The structures 316a are formed more densely than the structures 316b. For example, the structures 316a may be an array region of a memory device and the structures 316b may be in a periphery region of the memory device. The structures 316a and 316b are adjacent and separated by a gap 326. The illustrated semiconductor device 300 is merely exemplary and may also be a NOR flash, NROM (XtraROM), Mask ROM, NAND memory, Flash memory, other non-volatile memory, a general memory device, general semiconductor device, etc.

In addition to being provided in the structures 316a, the buffer dielectric layer 320 and the film 322 extends between the structures 316a to cover the region defined by the structures 316a. The buffer dielectric layer 320 and the film 322 do not cover the gap 326. The buffer dielectric layer 320 and the film 322 can be patterned in this manner during the formation of the stack structures 316a and 316b. Thus, the buffer dielectric layer 320 and the film 322 are self aligning and require few, if any, additional fabrication steps.

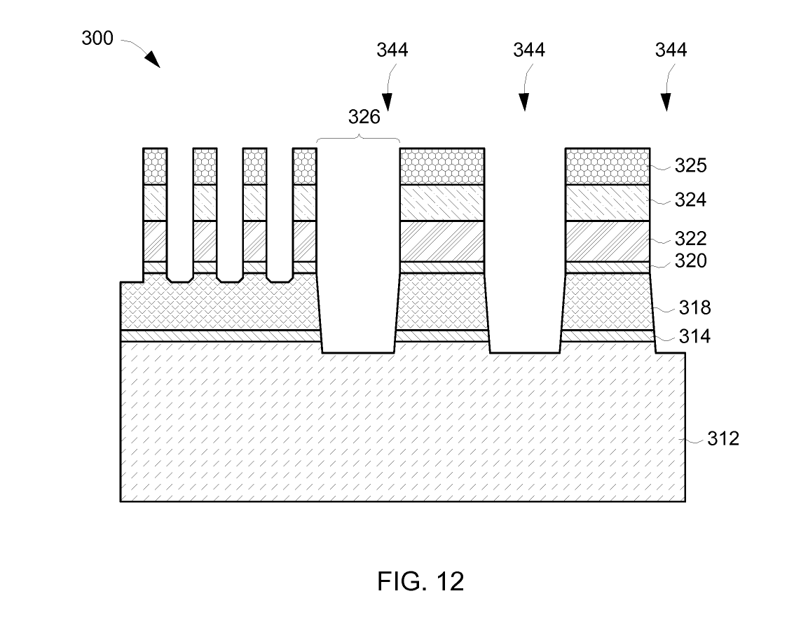

Referring to FIG. 12, an etching process is performed on the semiconductor device 300 shown in FIG. 11. The etching process is a selective etch that shows selectivity for the polysilicon layer 318 over the film 322. For example, if the film 322 is an SiN layer, then the etch may be a CF₄/CHF₃/HBr/N₂ recipe. This recipe has high selectivity for polysilicon over SiN. Though there may be some or a complete loss of the film 322 in the etching process, the selectivity of the etch provides for more significant etching in the region of the structures 316b and the gap 326, which does not include the film 322 between the structures or in the gap to slow/stop the etching process. Accordingly, the etching process provides for the formation of the trenches 344 in the region of the structures 316b and in the gap 326.

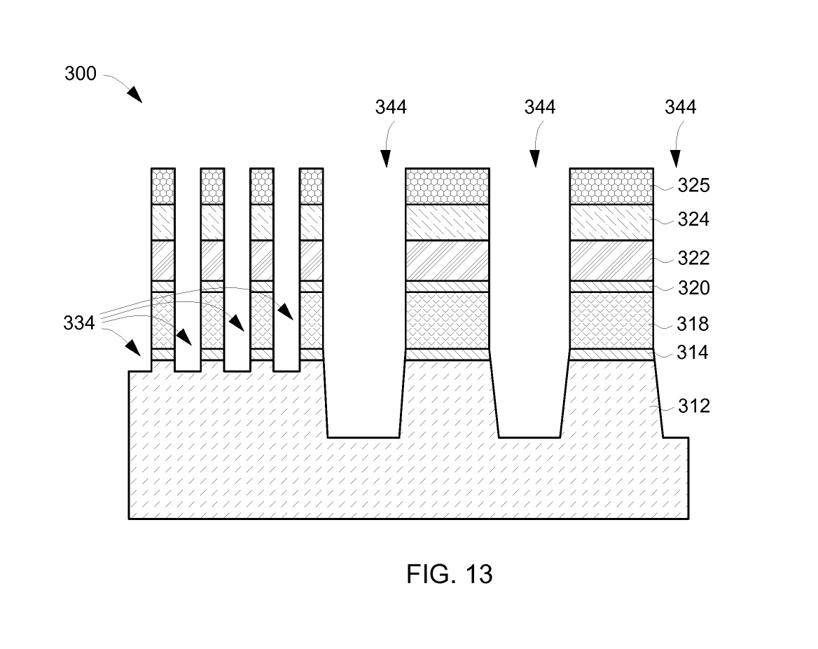

Referring to FIG. 13, an etching process is performed on the semiconductor device 300 shown in FIG. 12. The etching process may be a nonselective etch to etch through the polysilicon layer 318, the dielectric layer 314 and into the substrate 312 between the structures 316a to begin forming the trenches 334. The trenches 344 in the gap 326 and between the structures 316b are deepened in the substrate 312 by the etching process. The etching process may be a CF₄/CHF₃/N₂ etch.

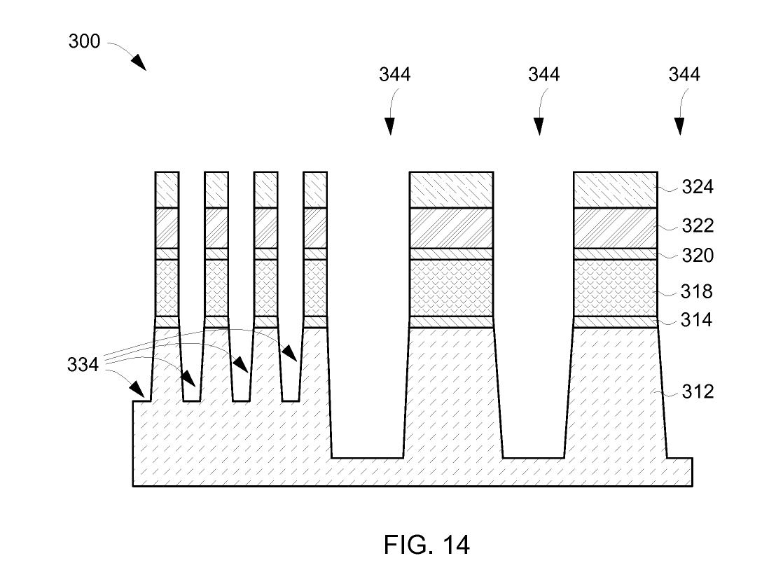

Referring to FIG. 14, a trenching step and the removal of the patterning film 325 is performed. The semiconductor device 300 includes trenches 334 in the region corresponding to the structures 316a and trenches 344 in the region corresponding to the structures 316b. In the gap 326, there is a trench corresponding to the depth of the trenches 344.

The described process of FIGS. 11-14 does not require additional lithography processes to separately mask the structures 316a and 316b. Thus, the etching of the trenches 334 and 344 can be performed in situ and sharp discontinuities, which can lead to stress cracks and fractures, are suppressed. In addition, the depth of the trench in the gap 326 is deep providing improved isolation between the structures 316a and 316b.

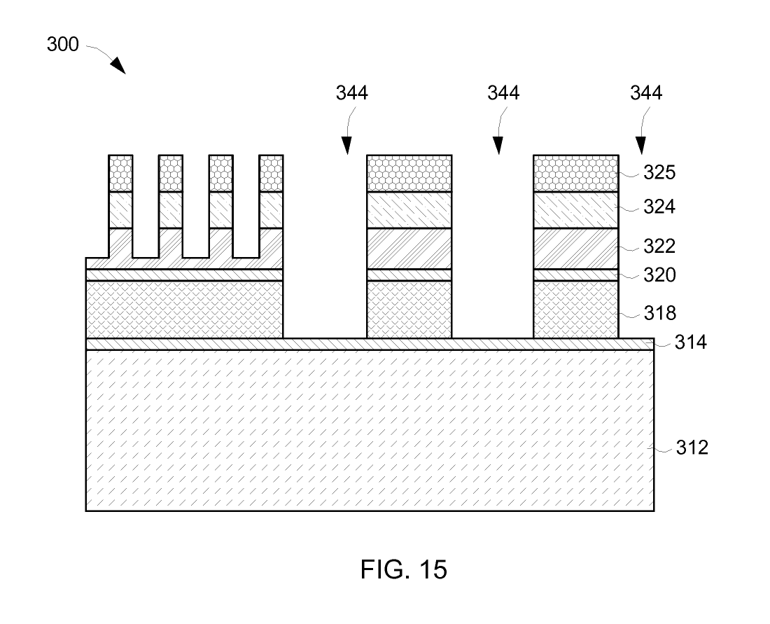

Referring to FIG. 15, an etching process is performed on the semiconductor device 300 shown in FIG. 11. The etching process is a selective etch that shows selectivity for the polysilicon layer 318 over the film 322. For example, if the film 322 is an SiN layer, then the etch may be a Cl₂/HBr/He—O₂ recipe. This recipe has high selectivity for polysilicon over SiN. The selectivity of the etch provides for more significant etching in the region of the structures 316b and the gap 326, which does not include the film 322 between the structures or in the gap to slow/stop the etching process. Accordingly, the etching process provides for the formation of the trenches 344 in the region of the structures 316b and in the gap 326. The etching process may also show selectivity against the dielectric layer 314 (e.g., oxide) such that the etching between the structures 316b and in the gap 326 forming the trenches 344 stops at the dielectric layer 314. There may be some loss of the film 322 in the etching process though if the selectivity against the film 322 and the dielectric layer 314 is high enough, the polysilicon layer 318 between the structures 316a may be minimally etched or not etched at all.

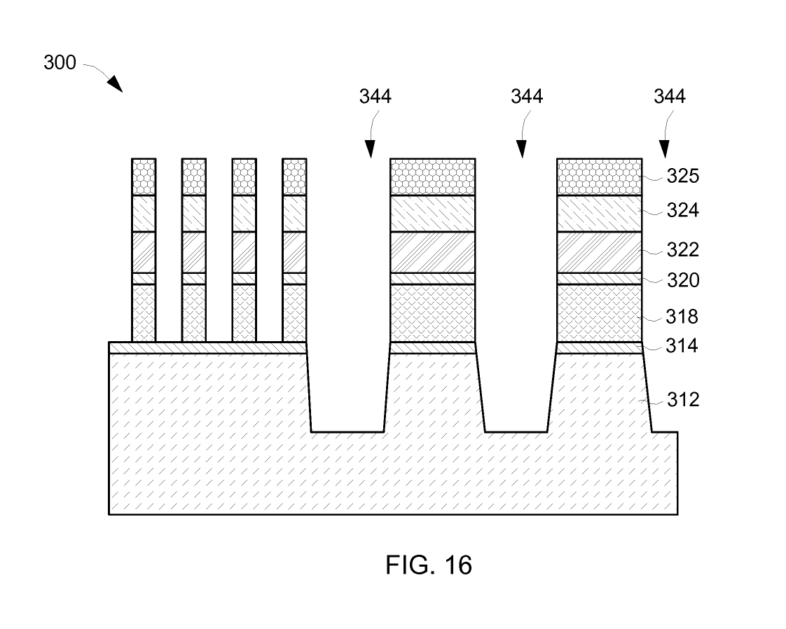

Referring to FIG. 16, an etching process is performed on the semiconductor device 300 shown in FIG. 15. The etching process may be a nonselective etch to etch through the polysilicon layer 318 between the structures 316a to begin forming the trenches 334. The etching process may also be a continuation of the etching process in the process corresponding to FIG. 15 (e.g., Cl₂/HBr/He—O₂). That is, the etching may proceed slowly through the film 322 and quickly through the polysilicon layer 318 thereby creating deeper trenches between the structures 316b then the structures 316a. In some embodiments, the etching stops with the dielectric layer 314 exposed between the structures 316a and the trenches 344 beginning to extend into the substrate 312.

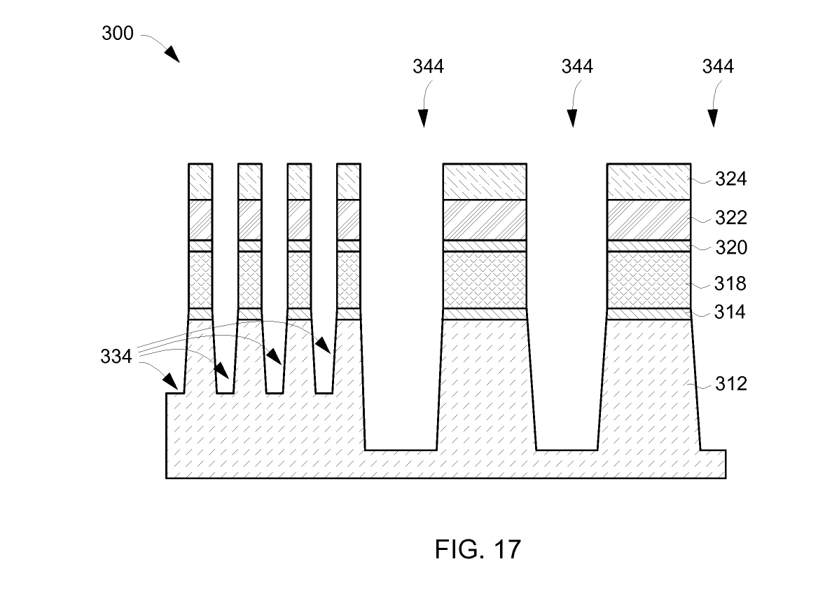

Referring to FIG. 17, a trenching step and the removal of the patterning film 325 is performed. The semiconductor device 300 includes trenches 334 in the region corresponding to the structures 316a and trenches 344 in the region corresponding to the structures 316b. In the gap 326, there is a trench corresponding to the depth of the trenches 344.

The described process of FIGS. 11 and 15-17 does not require additional lithography processes to separately mask the structures 316a and 316b. Thus, the etching of the trenches 334 and 344 can be performed in situ and sharp discontinuities, which can lead to stress cracks and fractures, are suppressed. In addition, the depth of the trench in the gap 326 is deep providing improved isolation between the structures 316a and 316b.

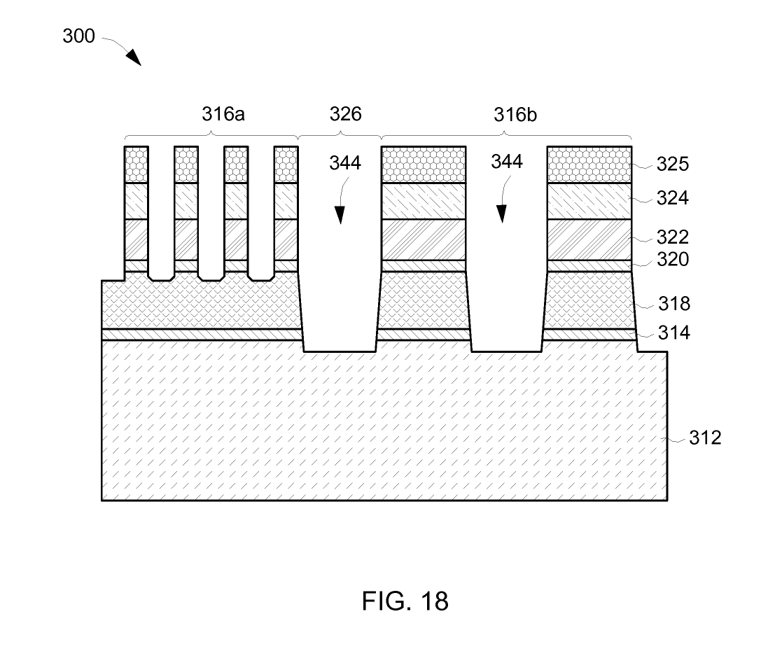

Referring to FIG. 18, an etching process is performed on the semiconductor device 300 shown in FIG. 11. The etching process is a selective etch that shows selectivity for the polysilicon layer 318 over the film 322. For example, if the film 322 is an SiN layer, then the etch may be a CF₄/CHF₃/HBr recipe. This recipe has high selectivity for polysilicon over SiN. The selectivity of the etch provides for more significant etching in the region of the structures 316b and the gap 326, which does not include the film 322 between the structures or in the gap to slow/stop the etching process. Accordingly, the etching process provides for the formation of the trenches 344 in the region of the structures 316b and in the gap 326.

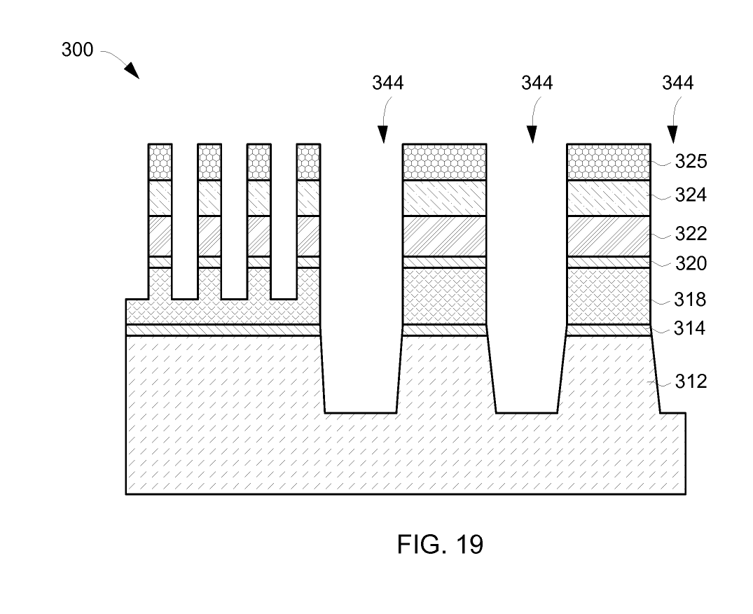

Referring to FIG. 19, an etching process is performed on the semiconductor device 300 shown in FIG. 18. The etching process may be a nonselective etch, such as CF₄/CHF₃/N₂, to etch into the polysilicon layer 318 between the structures 316a and into the substrate 312 between the structures 316b. The CF₄/CHF₃/N₂ etch may be provided in one or more steps. In some embodiments, two CF₄/CHF₃/N₂ etching steps are performed sequentially. Providing two (or more) etching steps allows for the use of a lower pressure such as 20-60 ml in a first step and a higher pressure such as 60-90 ml in a second step to provide a more vertical polysilicon profile.

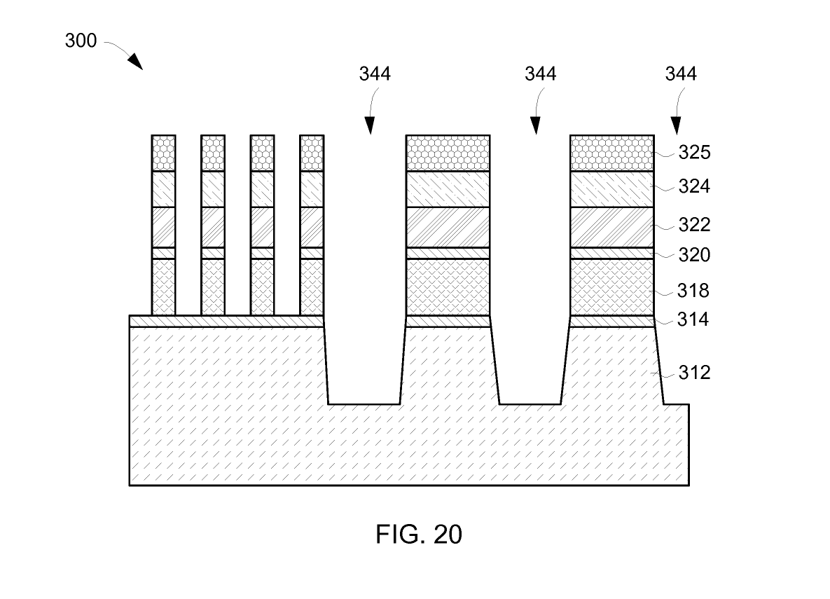

Referring to FIG. 20, an etching process, such as an HBr/He/He—O₂ etch, is performed to etch through the polysilicon layer 318 between the structures 316a and into the substrate 312 between the structures 316b. The HBr/He/He—O₂ etch provides high selectivity of polysilicon over oxide, particularly in a high pressure condition. Thus, this etching process may stop on oxide in the region of the structures 316a and continue to etch in the region of the structures 316b. This selectivity also allows more control of trench loading.

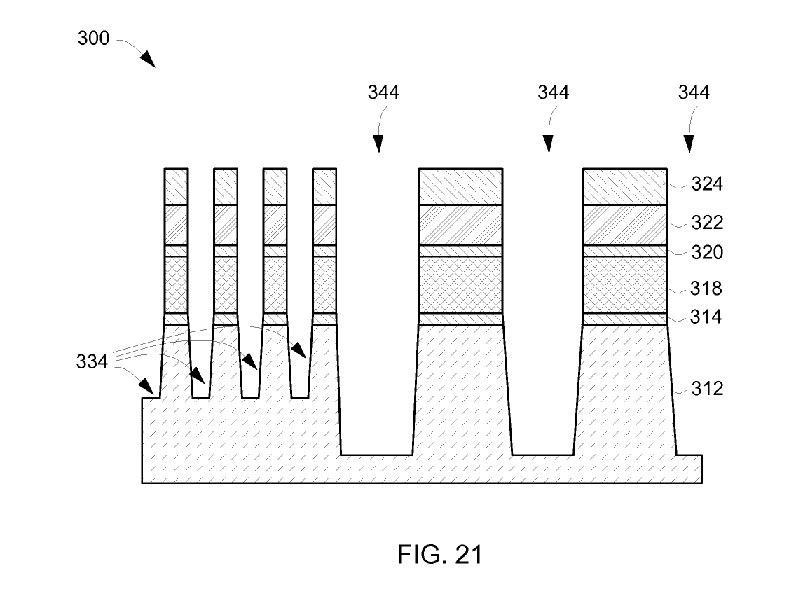

Referring to FIG. 21, a trenching step and the removal of the patterning film 325 is performed. The semiconductor device 300 includes the trenches 334 in the region corresponding to the structures 316a and the trenches 344 in the region corresponding to the structures 316b. In the gap 326, there is a trench corresponding to the depth of the trenches 344.

The described process of FIGS. 11 and 18-21 does not require additional lithography processes to separately mask the structures 316a and 316b. Thus, the etching of the trenches 334 and 344 can be performed in situ and sharp discontinuities, which can lead to stress cracks and fractures, are suppressed. In addition, the depth of the trench in the gap 326 is deep providing improved isolation between the structures 316a and 316b.

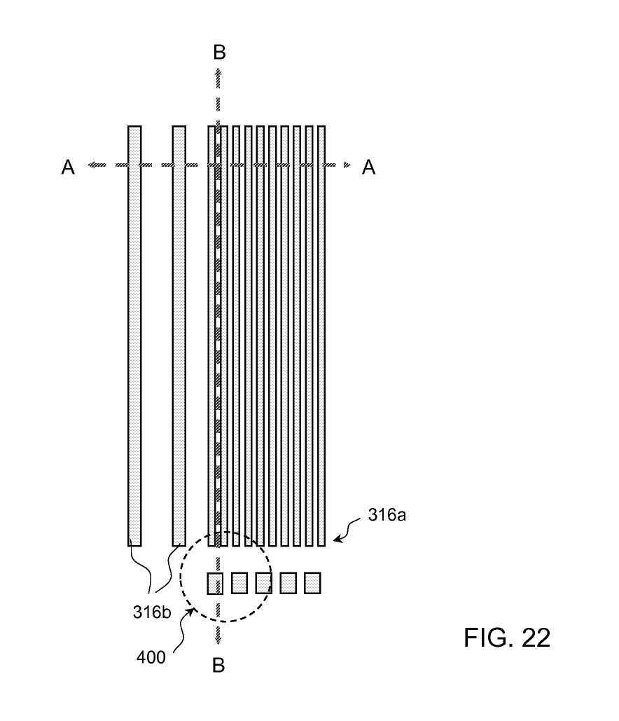

FIG. 22 is a top view of a semiconductor device 300 having a region of dense structures 316a, such as an array region, and a region of less dense structures 316b, such as a periphery region, around the region of dense structures 316a. The cross sectional views of FIGS. 11-20 correspond with a cut line such as the cut line A.

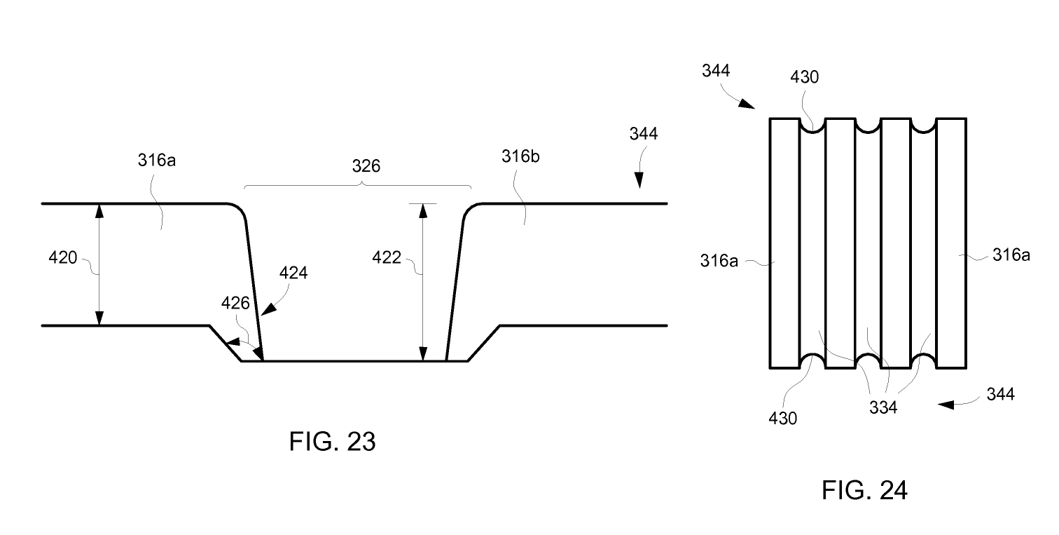

FIG. 23 illustrates a cross-sectional view of the semiconductor device 300 processed as in FIGS. 12-20 in the region 400 along the cut line B. The cut line B is along the trench 334 between the dense structures 316a. Thus, a side profile of a structure 316a is viewed. The depth 420 corresponds with the depth of the trenches 334. The gap 326 between the structure 316a and the structure 316b includes a trench of a depth 422 corresponding to the depth of the trenches 344.

Because the trenches 334 and 344 are etched by the same etching processes and there is not a mask layer covering the trenches 334 during the etching of the trenches 344, the transition 424 between the trench 334 and the trench 344 at the end of the array is smooth. That is, the sidewall is exposed during etching and some material is removed at the threshold between the different trench depths. An angle 426 of the sidewall at the transition between the trench 334 and the trench 344 is between 105 and 170 in some embodiments. This gentle transition reduces the risk of the formation of stress cracks and fractures as compared to the near 90 degree angle found in an abrupt transition, such as that shown in FIG. 9.

FIG. 24 illustrates a top view of the semiconductor device 300 processed as in FIGS. 12-20. Similar to the discussion above with respect to the angle of the sidewall, the exposure of the sidewall during the combined etching of the trenches 334 and 344 may result in the boundaries 430, in other words the etching front, between the trenches moving inwardly towards a middle of the structures 316a. The boundaries 430 may have a concave shape being deflected inwardly toward the structures 316a in some embodiments. In other embodiments, the boundaries may be V-shaped with the central portion of the V-shape extending inwardly towards the middle of the structures 316a.

Exemplary benefits of the described process include reduced complexity due to the reduction or elimination of extra lithography steps for STI formation; providing a self-aligned STI process; and improving reliability by suppressing stress cracks and fractures due to trench loading.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A semiconductor device, comprising:
a substrate; and
a first and second plurality of stack structures arranged over the substrate, the first plurality of stack structures being arranged more densely than the second plurality of stack structures, and the first and second plurality of stack structures being separated by a gap, wherein
the substrate includes a first trench between the structures of the first plurality of stack structures, a second trench between the structures of the second plurality of stack structures, and a third trench in the gap, and
a depth of the first trench is less than a depth of the third trench.

2. The semiconductor device of claim 1, wherein a depth of the second trench and the depth of the third trench is substantially the same.

3. The semiconductor device of claim 1, wherein the depth of the first trench is less than a depth of the second trench.

4. The semiconductor device of claim 1, wherein a maximum depth of the first trench is less than a maximum depth of the third trench.

5. The semiconductor device of claim 1, wherein a bottom of the third trench is continuous between a first sidewall of the third trench adjacent to one of the first stack structures and a second sidewall of the third trench adjacent to one of the second stack structures.

6. The semiconductor device of claim 1, further comprising
a sidewall between a portion of the first trench and a portion of the third trench, wherein
the sidewall forms an angle with the bottom of the trench, and
the angle is not ninety degrees.

7. The semiconductor device of claim 6, wherein the angle is between 105 degrees and 170 degrees.

8. The semiconductor device of claim 1, wherein the first stack structures are defined in an array region of a memory device and the second stack structures are defined in a periphery region of the memory device.

9. The semiconductor device of claim 1, further comprising
a boundary between a portion of the first trench and a portion of the third trench, wherein
the boundary is recessed inward toward a middle region of the first stack structures between the first stack structures.

10. The semiconductor device of claim 9, wherein the recess is concave deflected inwardly toward the middle region of the first stack structures.

11. The semiconductor device of claim 9, wherein the recess is V-shaped with a central portion of the V-shape extending inwardly toward the middle region of the first stack structures.

12. A method of manufacturing a semiconductor device, comprising:
providing a substrate;
forming a plurality of stack structures on the substrate, a portion of the stack structures being defined as an array region and a portion of the stack structures being defined as a periphery region; and
forming a plurality of trenches including a plurality of first trenches in the array region, a plurality of second trenches in the periphery region, and at least one third trench in the interface between the array region and the periphery region, wherein
the second trenches and the third trench are deeper than the first trenches.

13. The method of claim 12, wherein the forming a plurality of stack structures includes providing a barrier layer in and between the stack structures in the array region.

14. The method of claim 13, wherein the barrier layer is an SiN layer.

15. The method of claim 13, wherein the forming a plurality of trenches includes etching the semiconductor device with a selective etch.

16. The method of claim 15, wherein the selective etch is selective for a layer under the barrier layer as compared to the barrier layer.

17. The method of claim 16, wherein the layer under the barrier layer is polysilicon, the barrier layer is SiN, and the etch is SiN/polysilicon selective.

18. The method of claim 15, wherein the etch includes CF₄, CHF₃, HBr and N₂.

19. The method of claim 15, wherein the etch includes CL₂, HBr and He—O₂.

20. The method of claim 15, wherein the etch includes CF₄, CHF₃ and HBr.
